(19) United States
(12) Patent Application Publication
(10) Pub. No.: US 2021/0333453 A1
(43) Pub. Date: Oct. 28, 2021

(54) COLOR FILTER SUBSTRATE AND MANUFACTURING METHOD THEREOF

(71) Applicant: TCL CHINA STAR OPTOELECTRONICS TECHNOLOGY CO., LTD., Shenzhen (CN)

(72) Inventor: Jiangjiang SONG, Shenzhen (CN)

(73) Assignee: TCL CHINA STAR OPTOELECTRONICS TECHNOLOGY CO., LTD., Shenzhen (CN)

(21) Appl. No.: 16/626,526

(22) PCT Filed: Nov. 12, 2019
(86) PCT No.: PCT/CN2019/117592

§ 371 Date: Dec. 25, 2019

(30) Foreign Application Priority Data
Oct. 24, 2019 (CN) 201911018289.9

(51) Int. Cl. G02B 5/20; G03F 7/00

(52) U.S. Cl. CPC G02B 5/201; G02F 1/133516; G03F 7/0007

(57) ABSTRACT

A color filter substrate and a manufacturing method thereof are provided. The color filter substrate has a transparent substrate; a color resist layer formed on the transparent substrate, and the color resist layer has at least one recess and at least one flat portion; a transparent conductive layer formed on the color resist layer; and a black photosensitive layer formed on the transparent conductive layer. The black photosensitive layer has a first protruding portion and a second protruding portion. The first protruding portion is disposed on the recess and extends into the recess. The second protruding portion is disposed on the flat portion and a height of the second protruding portion is greater than a height of the first protruding portion.

### FIELD OF INVENTION

The present disclosure relates to a color filter substrate and a manufacturing method thereof, and more particularly, to a color filter substrate formed by using a half-tone mask and a black photosensitive layer, and a manufacturing method thereof.

### BACKGROUND OF INVENTION

With the development of display technology, liquid crystal display technology has become the mainstream of the current industry. Current liquid crystal display products include color filters, liquid crystal layers, array substrates, and backlight modules.

A current color filter includes a black matrix, a color layer, a transparent conductive layer, and spacers, which generally requires 5 lithography processes and 1 vacuum process for production. The spacers are classified into major spacers and minor spacers, and are generally produced by using a half-tone mask. In order to form the major and minor spacers with different heights, the designs of the half-tone mask and the corresponding processing steps are much complicated. Generally, the more the processes, the lower the corresponding yield. If the number of steps can be reduced, the yield of the product will be improved, and the production time will be shortened.

It is therefore necessary to provide a color filter substrate and a manufacturing method thereof in order to solve the problem existing in the conventional technology as described above.

### SUMMARY OF DISCLOSURE

### Technical Problem

A current color filter includes a black matrix, a color layer, a transparent conductive layer, and spacers, which generally requires 5 lithography processes and 1 vacuum process for production. The spacers are classified into major spacers and minor spacers, and are generally produced by using a half-tone mask. In order to form the major and minor spacers with different heights, the designs of the half-tone mask and the corresponding processing steps are much complicated. Generally, the more the processes, the lower the corresponding yield. If the number of steps can be reduced, the yield of the product will be improved, and the production time will be shortened.

### Technical Solutions

The primary object of the present disclosure is to provide a color filter substrate and a manufacturing method thereof. The color filter substrate has a plurality of protruding portions formed by a black photosensitive layer, and a plurality of recesses are arranged at specific positions of a color resist layer, so that the protruding portions have different heights for being served as major spacers and minor spacers. Since a half-tone mask can be used to produce different heights of the protruding portions during one mask process, a step of forming black matrix can be saved while process difficulties are reduced and product yield can be improved.

To achieve above objects, one embodiment of the present disclosure provides a color filter substrate, comprising: a transparent substrate; a color resist layer formed on the transparent substrate, wherein the color resist layer has at least one recess and at least one flat portion; a transparent conductive layer formed on the color resist layer; and a black photosensitive layer formed on the transparent conductive layer; wherein the black photosensitive layer comprise a first protruding portion and a second protruding portion, the first protruding portion is disposed on the recess and extends into the recess, the second protruding portion is disposed on the flat portion, and a height of the second protruding portion is greater than a height of the first protruding portion.

In one embodiment of the present disclosure, the color resist layer comprises a plurality of color resist blocks, and the recess is disposed at a junction between the color resist blocks.

In one embodiment of the present disclosure, the color resist layer comprises a first color resist block, a second color resist block, and a third color resist block, the recess is disposed at a first junction between the first color resist block and the second color resist block, and the flat portion is disposed at a second junction between the second color resist block and the third color resist block

In one embodiment of the present disclosure, the recess comprises a edge part of the color resist block, a thickness of the edge part is 0.8 to 1.5 μm less than a maximum thickness of the color resist layer.

In one embodiment of the present disclosure, the recess comprises a edge part of the color resist block, and a width of the edge part is ½-fold to ⅔-fold of a width of the first protruding portion.

In one embodiment of the present disclosure, the first protruding portion has a height ranging from 1.5 to 10 μm, and the second protruding portion has a height ranging from 2 to 10.5 μm.

In one embodiment of the present disclosure, a height of the first protruding portion is 0.3 to 0.8 μm smaller than a height of the second protruding portion.

Another embodiment of the present disclosure provides a manufacturing method of a color filter substrate, comprising steps of: providing a transparent substrate; forming a color resist layer on the transparent substrate, wherein the color resist layer has at least one recess and at least one flat portion; forming a transparent conductive layer on the color resist layer; and using a half-tone mask to form a black photosensitive layer on the transparent conductive layer; wherein the black photosensitive layer comprises a first protruding portion and a second protruding portion, the first protruding portion is disposed correspondingly on the recess and extends into the recess, the second protruding portion is disposed correspondingly on the flat portion, and a height of the second protruding portion is greater than a height of the first protruding portion.

In one embodiment of the present disclosure, the color resist layer comprises a plurality of color resist blocks, and the recess is disposed at a junction between the color resist blocks.

In one embodiment of the present disclosure, the color resist layer comprises a first color resist block, a second color resist block, and a third color resist block, the recess is disposed at a first junction between the first color resist block and the second color resist block, and the flat portion is disposed at a second junction between the second color resist block and the third color resist block.

In one embodiment of the present disclosure, the recess comprises a edge part of the color resist block, a thickness of the edge part is 0.8 to 1.5 μm less than a maximum thickness of the color resist layer.

In one embodiment of the present disclosure, the recess comprises a edge part of the color resist block, and a width of the edge part is ½-fold to ⅔-fold of a width of the first protruding portion.

In one embodiment of the present disclosure, the first protruding portion has a height ranging from 1.5 to 10 μm, and the second protruding portion has a height ranging from 2 to 10.5 μm.

In one embodiment of the present disclosure, a height of the first protruding portion is 0.3 to 0.8 μm smaller than a height of the second protruding portion.

### Beneficial Effects

The present disclosure provides a color filter substrate and a manufacturing method thereof. The color filter substrate has a plurality of protruding portions formed by a black photosensitive layer, and a plurality of recesses are arranged at specific positions on a color resist layer, so that the protruding portions have different heights for serving as major spacers and minor spacers. Since a half-tone mask can be used to produce the protruding portions of different heights during one mask process, a step of forming a black matrix can be omitted while the processing difficulty is reduced, and the product yield can be improved.

### BRIEF DESCRIPTION OF DRAWINGS

FIG. 1 is a top view of a color filter substrate according to one embodiment of the present disclosure.

FIG. 2 is a cross-sectional view of the color filter substrate taken along A-A′ of FIG. 1.

FIG. 3A to FIG. 3E are schematic views for showing a process flow of a manufacturing method of a color filter substrate according to one embodiment of the present disclosure.

### DETAILED DESCRIPTION OF PREFERRED EMBODIMENTS

The detailed description of the following embodiments is used for exemplifying the specific embodiments of the present disclosure by referring to the accompany drawings. Furthermore, directional terms described by the present disclosure, such as upper, lower, top, bottom, front, back, left, right, inner, outer, side, surrounding, center, horizontal, lateral, vertical, longitudinal, axial, radial, the uppermost, and lowermost, etc., are only directions by referring to the accompanying drawings, and thus the directional terms are used to describe and understand the present disclosure, but the present disclosure is not limited thereto.

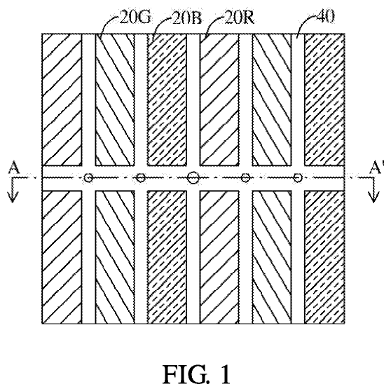

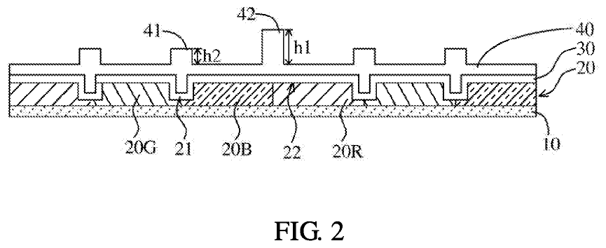

Referring to FIG. 1 and FIG. 2, a top view and a cross-sectional view of a color filter substrate are shown according one embodiment of the present disclosure. The color filter substrate mainly comprises: a transparent substrate 10; a color resist layer 20 formed on the transparent substrate 10, wherein the color resist layer 20 has at least one recess 21 and at least one flat portion 22; a transparent conductive layer 30 formed on the color resist layer 20; and a black photosensitive layer 40 formed on the transparent conductive layer 30; wherein the black photosensitive layer 40 comprises a first protruding portion 41 and a second protruding portion 42. The first protruding portion 41 is disposed on the recess 21 and extends into the recess 21. The second protruding portion 42 is disposed on the flat portion 22. Preferably, the second protruding portion 42 has a height h2 greater than a height h1 of the first protruding portion 41.

From FIG. 1, the black photosensitive layer 40 is arranged on the color resist layer 20, and the color resist layer 20 is divided into several blocks. These blocks allow light to pass through. Relatively, the portion covered by the black photosensitive layer 40 has a decreased light transmittance.

Referring to FIG. 2 again, in one embodiment of the present disclosure, the color resist layer 20 may includes a plurality of color resist blocks, such as a first color resist block 20G, a second color resist block 20B, and a third color resist block 20R. Preferably, the recess 21 is arranged at a first junction between the first color resist block 20G and the second color resist block 20B. The flat portion 22 is arranged at a second junction between the second color resist block 20B and the third color resist block 20R. Preferably, the recess 21 comprises a edge part of the first color resist block 20G, and a thickness of the edge part of the first color resist block 20G is 0.8 to 1.5 μm less than a maximum thickness of the color resist layer 20. That is, the edge part of the first color resist block 20G is thinner than the central part of the first color resist block. Similarly, the recess 21 also comprises a edge part of the second color resist block 20B. The edge part of the second color resist block 20B and the edge part of the first color resist block 20G together form the recess 21. The recess 21 can contain the first protruding portion 41, so that the height h1 of the first protruding portion 41 is less than the height h2 of the second protruding portion 42 located at the flat portion 22. In one embodiment of the present disclosure, the height of the first protruding portion 41 is 0.3 to 0.8 μm less than the height h2 of the second protruding portion 42. The first protruding portion 41 and the second protruding portion 42 can be spacers. Preferably, a width of the edge part of the first color resist block 20G and a width of the edge part of the second color resist block 20B are both ½-fold to ⅔-fold of a width of the first protruding portion 41. Preferably, the width of the first protruding portion 41 can be less than or equal to the width of the second protruding portion 42. In one embodiment of the present disclosure, the height h1 of the first protruding portion 41 ranges from 1.5 to 10 μm, and the height h2 of the second protruding portion 42 ranges from 2 to 10.5 μm.

Another embodiment of the present disclosure provides a manufacturing method of a color filter substrate. The manufacturing method comprises the following steps: (S1) providing a transparent substrate; (S2) forming a color resist layer on the transparent substrate; (S3) forming a transparent conductive layer on the color resist layer; and (S4) using a half-tone mask to form a black photosensitive layer on the transparent conductive layer. The black photosensitive layer is a photoresist material with black color and photosensitive property which can be patterned by irradiation, so as to make the black photosensitive layer have a specific layout. The black photosensitive layer may be a photoresist, for example, and is made of carbon black (or other black material) and acrylic as main ingredients.

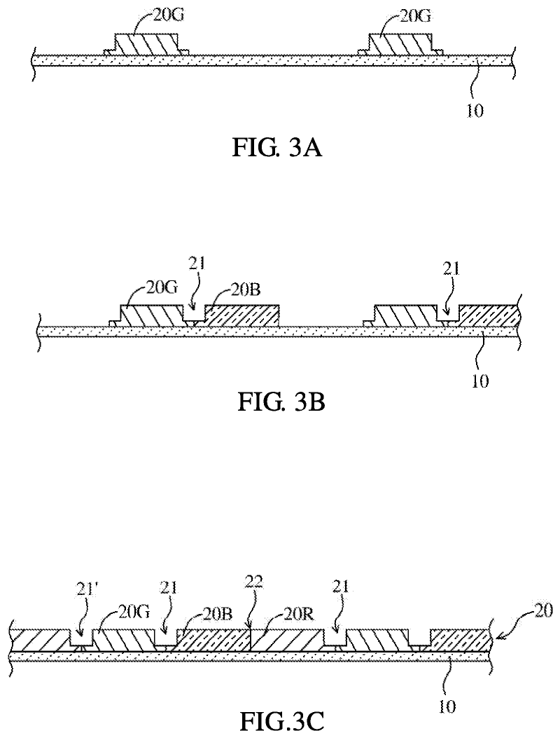

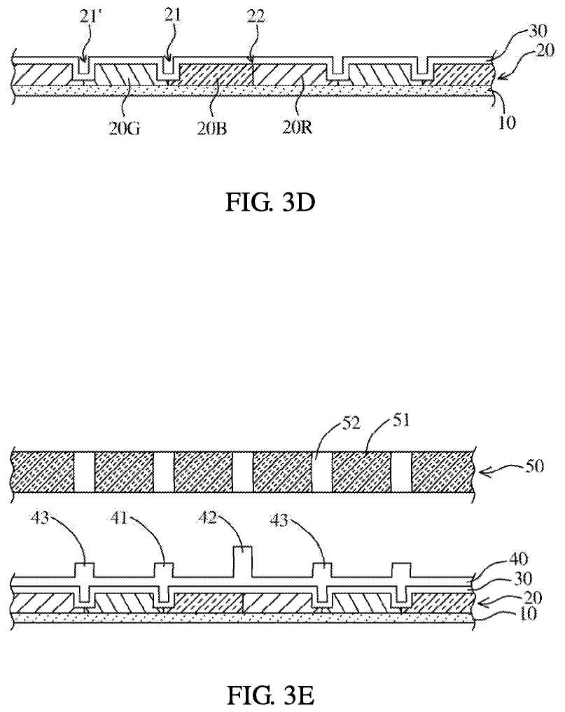

As shown in FIG. 3A to FIG. 3C, the steps (S1) and (S2) may be performed by forming several first color resist blocks 20G on the transparent substrate 10 first, then forming a second color resist block 20B adjacent the right side of each of the first color resist block 20G, and finally, forming a third color resist block 20R adjacent the right side of each of the second color resist block 20B. Thus, the color resist layer 20 has the first color resist block 20G, the second color resist block 20B, and the third color resist block 20R in order, i.e. a green color resist block, a blue color resist block 20B, and red color resist block, but is not limited thereto. The first color resist block 20G, the second color resist block 20B, and the third color resist block 20R included in the color resist layer 20 can be formed, for example, by a yellow lithography process, respectively. When the first color resist block 20G is being formed, the thickness of the right edge part of the first color resist block 20G is thinned to be combined with the left edge part of the edge part of the second color resist block 20B to form a recess 21 in the following steps. Similarly, when the second color resist block 20B is being formed, the thickness of the left edge part is also thinned. Because the color resist layer 20 is disposed on the transparent substrate 10 by sequentially arranging the first color resist block 20G, the second color resist block 20B, and the third color resist block 20R in a regular order, preferably, the right edge part of the third color resist block 20R and the left edge part of the first color resist block 20G (i.e. at the junction) form another recess 21′. However, the junction between the second color resist block 20B and the third color resist block 20R is not thinned, so that a flat portion 22 is formed. The recess 21′ may optionally be formed or not be formed. Alternatively, the position of the recess 21 maybe changed, and the present disclosure is not limit thereto. Therefore, the positions and the numbers of the recess may be modified depending on the actual situation.

Afterward, as shown in FIG. 3D, in the step (S3), the transparent conductive layer 30 is formed on the color resist layer 20. The transparent conductive layer 30 may be, for example, deposited on the color resist layer 20 by physical vapor deposition (PVD). The materials of the transparent conductive layer 30 are transparent conductive materials, such as indium tin oxide, or indium zinc oxide, but are not limited thereto.

Referring to FIG. 3E, in the step (S4), the half-tone mask 50 has several translucent areas 51 and several totally transparent areas 52. The totally transparent areas 52 are aligned correspondingly to the recess 21, the recess 21′, and the flat portion 22 to performing exposure and development, so that the black photosensitive layer 40 forms a first protruding portion 41, a second protruding portion 42, and a third protruding portion 43. The translucent areas 51 shield a part of light, so that the positions of the black photosensitive layer 40 aligned to these translucent areas 51 undergo an incomplete reaction, and most of the materials are removed after development. On the contrary, the reaction occurring to the positions in the fully transparent areas 52 is relatively complete, and therefore the black photosensitive layer 40 having a high and low morphology is obtained by the half-tone mask 50. The first protruding portion 41 is aligned to the recess 21 and extends into the recess 21, the second protruding portion 42 is aligned to the flat portion 22. Therefore, the height of the second protruding portion 42 is greater than the height of the first protruding portion 41. Similarly, the third protruding portion 43 is formed on the recess 21′, and the height of the first protruding portion 41 and the height of the third protruding portion 43 are both less than the height of the second protruding portion 42.

In one embodiment of the present disclosure, the height of the first protruding portion 41 is 0.3 to 0.8 μm less than the height of the second protruding portion 42. The first protruding portion 41, the second protruding portion 42, and the third protruding portion 43 can serve as spacers of a liquid crystal panel. The second protruding portion 42 is highest to be a major spacer, and the first protruding portion 41 and/or the third protruding portion 43 are/serve as minor spacers. Preferably, a width of the right edge part of the first color resist block 20G and a width of the left edge part of the second color resist block 20B are both ½ to ⅔-fold of a width of the first protruding portion 41. Preferably, both of the widths of the first protruding portion 41 and the third protruding portion 43 may be less than or equal to the width of the second protruding portion 42. However, if the width of the first protruding portion 41 or the width of the third protruding portion 43 is greater than the width of the second protruding portion 42, the function as a spacer is not affected. In one embodiment of the present disclosure, the height of the first protruding portion 41, the height of the second protruding portion 42, and the height of the third protruding portion 43 are all 2 to 4 μm. the height h1 of the first protruding portion 41 ranges from 1.5 to 10 μm, and the height h2 of the second protruding portion 42 ranges from 2 to 10.5 μm.

The present disclosure has been described by the above related embodiments, but the above embodiments are merely examples for implementing the present disclosure. It must be noted that the disclosed embodiments do not limit the scope of the present disclosure. Rather, modifications and equivalent arrangements included in the spirit and scope of the claims are intended to be included within the scope of the present disclosure.

What is claimed is:

1. A color filter substrate, comprising:
a transparent substrate;
a color resist layer formed on the transparent substrate, wherein the color resist layer has at least one recess and at least one flat portion;
a transparent conductive layer formed on the color resist layer; and
a black photosensitive layer formed on the transparent conductive layer;
wherein the color resist layer comprises a plurality of color resist blocks, and the recess is disposed at a junction between the color resist blocks;
the black photosensitive layer comprise a first protruding portion and a second protruding portion, wherein the first protruding portion is disposed on the recess and extends into the recess, the second protruding portion is disposed on the flat portion, and a height of the first protruding portion is 0.3 to 0.8 μm smaller than a height of the second protruding portion.

2. The color filter substrate according to claim 1, wherein the color resist layer comprises a first color resist block, a second color resist block, and a third color resist block, the recess is disposed at a first junction between the first color resist block and the second color resist block, and the flat portion is disposed at a second junction between the second color resist block and the third color resist block.

3. The color filter substrate according to claim 1, wherein the recess comprises a edge part of the color resist block, and a width of the edge part is ½-fold to ⅔-fold of a width of the first protruding portion.

4. A color filter substrate, comprising:
a transparent substrate;
a color resist layer formed on the transparent substrate, wherein the color resist layer has at least one recess and at least one flat portion;
a transparent conductive layer formed on the color resist layer; and
a black photosensitive layer formed on the transparent conductive layer;
wherein the black photosensitive layer comprises a first protruding portion and a second protruding portion, the first protruding portion is disposed on the recess and extends into the recess, the second protruding portion is disposed on the flat portion, and a height of the second protruding portion is greater than a height of the first protruding portion.

5. The color filter substrate according to claim 4, wherein the color resist layer comprises a plurality of color resist blocks, and the recess is disposed at a junction between the color resist blocks.

6. The color filter substrate according to claim 5, wherein the color resist layer comprises a first color resist block, a second color resist block, and a third color resist block, the recess is disposed at a first junction between the first color resist block and the second color resist block, and the flat portion is disposed at a second junction between the second color resist block and the third color resist block.

7. The color filter substrate according to claim 5, wherein the recess comprises a edge part of the color resist block, and a width of the edge part is ½-fold to ⅔-fold of a width of the first protruding portion.

8. The color filter substrate according to claim 4, wherein a height of the first protruding portion is 0.3 to 0.8 μm smaller than a height of the second protruding portion.

9. A manufacturing method of a color filter substrate, comprising steps of:
providing a transparent substrate;
forming a color resist layer on the transparent substrate, wherein the color resist layer has at least one recess and at least one flat portion;
forming a transparent conductive layer on the color resist layer; and
using a half-tone mask to form a black photosensitive layer on the transparent conductive layer;
wherein the black photosensitive layer comprises a first protruding portion and a second protruding portion, the first protruding portion is disposed correspondingly on the recess and extends into the recess, the second protruding portion is disposed correspondingly on the flat portion, and a height of the second protruding portion is greater than a height of the first protruding portion.

10. The manufacturing method of a color filter substrate according to claim 9, wherein the color resist layer comprises a plurality of color resist blocks, and the recess is disposed at a junction between the color resist blocks.

11. The manufacturing method of a color filter substrate according to claim 10, wherein the color resist layer comprises a first color resist block, a second color resist block, and a third color resist block, the recess is disposed at a first junction between the first color resist block and the second color resist block, and the flat portion is disposed at a second junction between the second color resist block and the third color resist block.

12. The manufacturing method of a color filter substrate according to claim 10, wherein the recess comprises a edge part of the color resist block, and a width of the edge part is ½-fold to ⅔-fold of a width of the first protruding portion.

13. The manufacturing method of a color filter substrate according to claim 9, wherein a height of the first protruding portion is 0.3 to 0.8 μm smaller than a height of the second protruding portion.
